(19) United States
(12) Patent Application Publication
(10) Pub. No.: US 2026/0362887 A1
(43) Pub. Date: Nov. 12, 2026

(54) INTEGRATED ENERGY-COLLECTING DISPLAY MODULE

(71) Applicant: Garmin International, Inc., Olathe, KS (US)

(72) Inventors: Wen-Yu Wu, New Taipei City (TW); Ching-Hsuan Peng, New Taipei City (TW)

(21) Appl. No.: 19/202,365

(22) Filed: May 8, 2025

(51) Int. Cl. H10H 29/85; H10F 19/80

(52) U.S. Cl. CPC H10H 29/8517; H10F 19/80

(57) ABSTRACT

A display module for use with a wrist-worn electronic device comprises a plurality of layers positioned one on top of another to form a stack. The layers from bottom to top include a light-emitting diode (LED) pixel layer, a thin film encapsulation (TFE) layer, a color filter layer, and a photovoltaic layer, among others. The LED pixel layer includes a plurality of pixels, each pixel including a red subpixel, a green subpixel, and a blue subpixel. The TFE layer provides a moisture barrier for the LED pixel layer. The color filter layer includes a plurality of color filters, each color filter including a red subfilter, a green subfilter, and a blue subfilter, and a plurality of filter windows, each filter window positioned between respective adjacent subfilters. The photovoltaic layer includes a plurality of photovoltaic elements to convert optical energy to electrical energy and a plurality of photovoltaic windows.

### BACKGROUND

Electronic devices worn on a user’s wrist include smart watches and fitness bands and typically have a color display which displays data and images. In addition, the devices are powered by a rechargeable battery. To increase the amount of time before the battery needs to be charged, the electronic device may also include a solar cell of photovoltaic elements which is positioned over the display.

### BRIEF DESCRIPTION OF DRAWINGS

Embodiments of the present technology are described in detail below with reference to the attached drawing figures, wherein:

FIG. 1 is a perspective view of an electronic device constructed in accordance with various embodiments of the present technology, the electronic device including an improved display module;

FIG. 2 is a schematic block diagram illustrating communication between various electronic components of the electronic device;

FIG. 3 is a schematic block diagram of a cross section of the display module;

FIG. 4 is a top view of a light-emitting diode (LED) pixel layer of the display module;

FIG. 5 is a top view of a color filter layer of the display module;

FIG. 6 is a top view of a photovoltaic layer of the display module; and

FIG. 7 is a schematic block diagram of a portion of the cross section of the display module illustrating an operation of the display module.

The drawing figures do not limit the present technology to the specific embodiments disclosed and described herein. The drawings are not necessarily to scale, emphasis instead being placed upon clearly illustrating the principles of the technology.

### DETAILED DESCRIPTION OF THE TECHNOLOGY

The following detailed description of the technology references the accompanying drawings that illustrate specific embodiments in which the technology can be practiced. The embodiments are intended to describe aspects of the technology in sufficient detail to enable those skilled in the art to practice the technology. Other embodiments can be utilized and changes can be made without departing from the scope of the present technology. The following detailed description is, therefore, not to be taken in a limiting sense. The scope of the present technology is defined only by the appended claims, along with the full scope of equivalents to which such claims are entitled.

Relational and/or directional terms, such as “above”, “below”, “up”, “upper”, “upward”, “down”, “lower”, “downward”, “top”, “bottom”, “outer”, “inner”, “left”, “right”, etc., along with orientation terms, such as “horizontal” and “vertical”, may be used throughout this description. These terms retain their commonly accepted definitions and are used with reference to embodiments of the technology and the positions, directions, and orientations thereof shown in the accompanying figures. However, embodiments of the technology in practice may be positioned and oriented in other ways or move in other directions. Therefore, the terms do not limit the scope of the current technology.

In the following description, the word “voltage” may be used to describe electric voltage, the word “current” may be used to describe electric current, and the word “power” may be used to describe electric power. In addition, the word “signal” may be used to describe an electromagnetic wave conducted through an electrically conductive medium in which a voltage and/or a current varies, or may be constant, over time.

Embodiments of the present technology relate to a wrist-worn electronic device including an improved display module that has greater color depth and increased apparent brightness. An exemplary electronic device, as shown in the figures, may be embodied by a smart watch or a fitness band that is typically worn on a user’s wrist, but may also be embodied by bands or belts worn on the user’s arm, leg, or torso. Other examples of the electronic device may include smartphones, personal data assistants, or the like. The electronic device comprises a display module that includes an array of light-emitting diode (LED) pixels to display images and information, with each LED pixel including a red subpixel, a green subpixel, and a blue subpixel. The electronic device is also electrically powered by a rechargeable battery. Thus, it is desirable to incorporate a photovoltaic (PV) element, such as a solar cell, in the electronic device to convert ambient light, including sunlight, into electrical energy which increases battery charge. In order to provide the most benefit, the PV element should be as large as possible and placed where it can receive the most ambient light. A likely location would be the face of the electronic device where the PV element is incorporated with the display module and positioned over the LED pixel array. However, such a positioning of the PV element would obscure the LED pixel array. One approach to minimize obscuring the display module is to form or fabricate the PV element to be partially transparent such that the PV element includes a plurality of smaller interconnected PV elements that are laterally spaced apart from one another in an array with a respective one of a plurality of transparent windows between adjacent PV elements. The PV element array can still be positioned over the LED pixel array and allow some level of visibility of the LED pixel array. Unfortunately, this approach is still less than optimal because the display module, with the PV element array over the LED pixel array, appears dull and lacks brightness and contrast.

As described in detail below, the PV element array may be implemented as a discrete, self-contained module that can be fabricated and tested independently and subsequently applied to a preassembled display stack as a functional energy-harvesting add-on. This configuration enables scalable post-processing, including retrofit applications or iterative prototyping, without requiring modification to the underlying LED pixel architecture or display emission characteristics.

Embodiments of the present electronic device provide a solution that offers a more vibrant display module by including a color filter array that is positioned between the LED pixel array and the PV element array. The color filter array includes a plurality of color filters, with each color filter including a red subfilter, a green subfilter, and a blue subfilter. The subfilters are spaced apart laterally, with a respective one of a plurality of transparent windows positioned between adjacent subfilters. The pitch, i.e., the spacing, between the color filters in the color filter array is approximately the same as the pitch between the LED pixels in the LED pixel array such that each LED pixel is vertically aligned with a respective one of the color filters. In addition, the subfilters are positioned for each color filter such that the individual color subfilters of each color filter are vertically aligned the respective color subpixels of a respective one of the LED pixels. That is, the red subfilter is vertically aligned with the red subpixel, the green subfilter is vertically aligned with the green subpixel, and the blue subfilter is vertically aligned with the blue subpixel.

In various embodiments, the LED pixel array further includes a plurality of optical reflectors configured to reflect light in the visible spectrum, with each optical reflector being positioned between adjacent subpixels. The color filter array also aligns with the LED pixel array such that each optical reflector is vertically aligned with a respective one of the windows of the color filter array.

Furthermore, the color filter array aligns with the PV element array such that each subfilter is vertically aligned with a respective one of the windows of the PV element array, and each window of the color filter array is vertically aligned with a respective one of the PV elements.

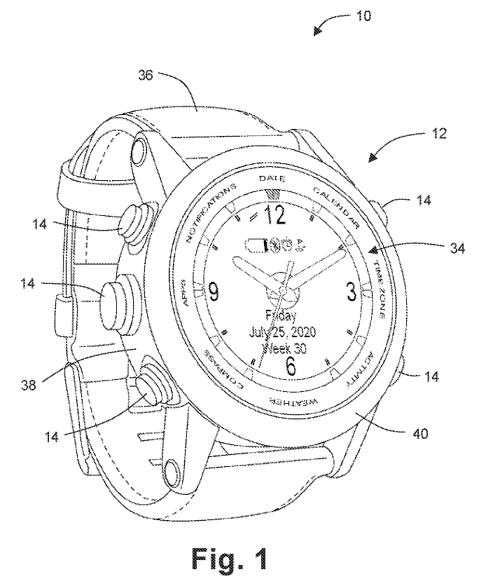

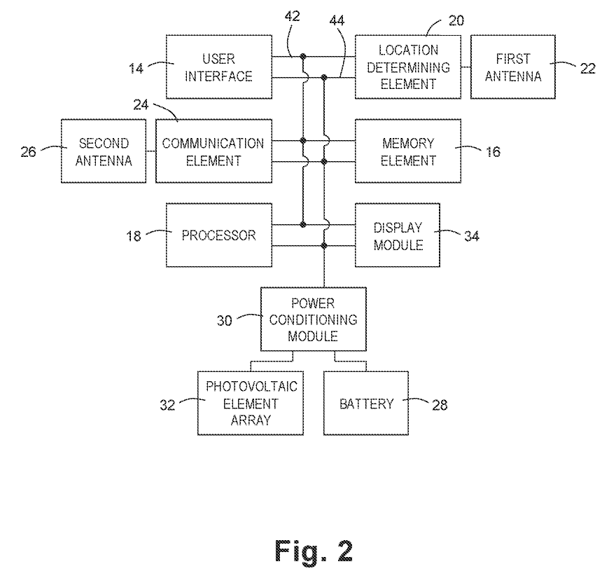

Embodiments of the technology will now be described in more detail with reference to the drawing figures. Referring initially to FIGS. 1 and 2, a wrist-worn electronic device 10 is illustrated. The electronic device 10 broadly comprises a housing 12, a user interface 14, a memory element 16, a processor 18, a location determining element 20, a first antenna 22, a communication element 24, a second antenna 26, a battery 28, a power conditioning module 30, a photovoltaic element array 32, and a display module 34. The electronic device 10 may also include a wrist band 36, a strap, or other attachment mechanisms.

The housing 12, as shown in FIG. 1, generally houses or retains other components of the electronic device 10 and may include or be coupled to the wrist band 36. The housing 12 includes a bottom wall (not visible in the figures), a side wall 38, and a bezel 40. A lower edge of the side wall 38 is connected to the bottom wall. An upper edge of the side wall 38 is connected to the bezel 40, which includes a central opening. The bottom wall, the side wall 38, and the bezel 40 in combination form, or define the boundaries of, an internal cavity of the housing 12 in which the other listed components are positioned.

In exemplary embodiments, the housing 12 generally has a rounded or circular shape, wherein the bottom wall has a disc shape, the side wall 38 has a hollow cylindrical shape, and the bezel 40 has an annular shape. In other embodiments, the housing 12 may have one of a variety of geometric or polygonal shapes, such as triangular, square or rectangular, hexagonal, octagonal, and so forth.

The user interface 14 generally allows the user to directly interact with the electronic device 10 and may include pushbuttons, rotary knobs, or the like. In exemplary embodiments of FIG. 1, the housing 12 may include one or more pushbuttons and/or rotary knobs located in the through holes of the side wall 38 that function as at least a portion of the user interface 14. The user interface 14 may allow the user to scroll through menus or change screens in order to control the function or operation of the electronic device 10.

The memory element 16 may be embodied by devices or components that store data in general, and digital or binary data in particular, and may include exemplary electronic hardware data storage devices or components such as read-only memory (ROM), programmable ROM, erasable programmable ROM, random-access memory (RAM) such as static RAM (SRAM) or dynamic RAM (DRAM), cache memory, hard disks, optical disks, flash memory, thumb drives, universal serial bus (USB) drives, solid state memory, or the like, or combinations thereof. In some embodiments, the memory element 16 may be embedded in, or packaged in the same package as, the processor 18. The memory element 16 may include, constitute, or embody, a non-transitory “computer-readable medium”. The memory element 16 may store the instructions, code, code statements, code segments, software, firmware, programs, applications, apps, services, daemons, or the like that are executed by the processor 18. The memory element 16 is in electronic communication with the processor 18 and may also store data that is received by the processor 18 or the device in which the processor 18 is implemented. The processor 18 may further store data or intermediate results generated during processing, calculations, and/or computations as well as data or final results after processing, calculations, and/or computations. In addition, the memory element 16 may store settings, lookup tables, text data, documents from word processing software, spreadsheet software and other software applications, sampled audio sound files, photograph or other image data, movie data, databases, and the like.

The processor 18 may comprise one or more processors that include electronic hardware components such as microprocessors (single-core or multi-core), microcontrollers, digital signal processors (DSPs), field-programmable gate arrays (FPGAs), analog and/or digital application-specific integrated circuits (ASICs), intelligence circuitry, or the like, or combinations thereof. The processor 18 may generally execute, process, or run instructions, code, code segments, code statements, software, firmware, programs, applications, apps, processes, services, daemons, or the like. The processor 18 may also include hardware components such as registers, finite-state machines, sequential and combinational logic, configurable logic blocks, and other electronic circuits that can perform the functions necessary for the operation of the current invention. In certain embodiments, the processor 18 may include multiple computational components and functional blocks that are packaged separately but function as a single unit. In some embodiments, the processor 18 may further include multiprocessor architectures, parallel processor architectures, processor clusters, and the like, which provide high performance computing. The processor 18 may be in electronic communication with the other electronic components of the electronic device 10 through serial or parallel links that include universal busses, address busses, data busses, control lines, and the like. In addition, the processor 18 may include analog to digital converters (ADCs) to convert analog electronic signals to digital data values in binary form (such as by sampling), or streams of digital data values, and/or digital to analog converters (DACs) to convert digital data values, or streams of digital data values, to analog electronic signals.

The location determining element 20 generally determines a current geolocation of the electronic device 10 and may receive and process radio frequency (RF) wireless signals from a multi-constellation global navigation satellite system (GNSS) such as the global positioning system (GPS) utilized in the United States, the Galileo system utilized in Europe, the GLONASS system utilized in Russia, or the like. The location determining element 20 may include satellite navigation receivers, processors, controllers, other computing devices, or combinations thereof, and memory. The location determining element 20 may process a location electronic signal communicated from the first antenna 22, which receives the location wireless signal from one or more satellites of the GNSS. The location wireless signal includes data from which geographic information such as the current geolocation is derived. The current geolocation may include coordinates, such as the latitude and longitude, of the current location of the electronic device 10. The location determining element 20 may communicate the current geolocation to the processor 18, the memory element 16, or both.

Although embodiments of the location determining element 20 may include a satellite navigation receiver, it will be appreciated that other location-determining technology may be used. For example, cellular towers or any customized transmitting radio frequency towers can be used instead of satellites may be used to determine the location of the electronic device 10 by receiving data from at least three transmitting locations and then performing basic triangulation calculations to determine the relative position of the device with respect to the transmitting locations. With such a configuration, any standard geometric triangulation algorithm can be used to determine the location of the electronic device 10. The location determining element 20 may also include or be coupled with a pedometer, accelerometer, compass, or other dead-reckoning components which allow it to determine the location of the electronic device 10. The location determining element 20 may determine the current geographic location through a communications network, such as by using Assisted GPS (A-GPS), or from another electronic device. The location determining element 20 may even receive location data directly from a user.

The first antenna 22 converts wireless RF electromagnetic radiation (a wireless signal) at a particular frequency, i.e., a resonant frequency, into a corresponding electronic signal and converts an electronic signal into a corresponding wireless signal. The first antenna 22 may be implemented as a loop antenna, a microstrip antenna, a patch antenna, a linear antenna, an inverted F-antenna, an inverted L-antenna, a dipole antenna, or the like. The first antenna 22 is configured to receive location wireless signal from one or more satellites of the GNSS. For example, the first antenna 22 may receive a first location wireless signal output by GPS satellites and having a frequency in the GPS L1 band, which has a center frequency of approximately 1575 MHz. In addition, or instead, the first antenna 22 may receive a second location wireless signal output by GPS satellites and having a frequency in the GPS L5 band, which has a center frequency of approximately 1175 MHz. The first antenna 22 outputs or communicates the location electronic signal, corresponding to the first location wireless signal and/or the second location wireless signal, which is received and processed by the location determining element 20.

The communication element 24 processes a communication electronic signal that allows the electronic device 10 to communicate with other electronic devices, external systems, networks, such as a Bluetooth™ network and/or a long-term evolution (LTE) cellular network. The communication element 24 communicates the communication electronic signal with the second antenna 26. The communication element 24 may include signal and/or data transmitting and receiving circuits, such as amplifiers, filters, mixers, oscillators, DSPs, and the like that process RF electronic signals which include data transmitted and received using various communication standards. The communication element 24 processes the communication electronic signal with a frequency component ranging from approximately 2.40 gigahertz (GHz) to approximately 2.4835 GHz and includes data associated with communication standards such as ANT, ANT+, Bluetooth™, Bluetooth™ low energy (BLE), the industrial, scientific, and medical (ISM) band at 2.4 GHz, or the like. In addition, or instead, the communication electronic signal may include data that is associated with various Institute of Electrical and Electronics Engineers (IEEE) 802.11 Wi-Fi standards operating at 2.4 GHz. In other embodiments, the communication element 24 may be utilized to process the communication electronic signal with a frequency component at approximately 860 MHz (MHz) to and includes data associated with communication standards utilized in cellular communications, such as LTE (low band LTE commonly uses frequencies ranging from approximately 600 MHz to approximately 900 MHz). The communication element 24 in electronic communication with the second antenna 26, the memory element 16 and the processor 18.

The second antenna 26 operates in the same, or a similar, fashion to the first antenna 22 and may be implemented as a loop antenna, a microstrip antenna, a patch antenna, a linear antenna, an inverted F-antenna, an inverted L-antenna, a dipole antenna, or the like. The second antenna 26 is configured to transmit and receive common wireless communication protocols such as Bluetooth™, WiFi, and/or LTE signals. The second antenna 26 also communicates the communication electronic signal, corresponding to the wireless signal of the aforementioned protocols, to the communication element 24.

The electronic device 10 further includes a signal bus 42 provides electronic communication between at least a portion of the user interface 14, the memory element 16, the processor 18, the location determining element 20, the communication element 24, and the display module 34. The signal bus 42 may include a serial communication line, parallel communication lines (such as 8-bit, 16-bit, 32-bit, 64-bit, etc.), or a combination of both.

The battery 28 is an electric voltage or charge source that provides electric power for the electronic device 10. Exemplary embodiments of the battery 28 include a rechargeable battery configured to accept an electric charge after charge levels of the battery 28 have been depleted. The battery 28 may receive the electric charge from an external electric power source through a connector that attaches to the housing 12 and/or through inductive charging components. The battery 28 further receives the electric charge from the photovoltaic element array 32 through the power conditioning module 30.

The power conditioning module 30 may act as an interface between the battery 28 and the other components of the electronic device 10 which require electric power. The power conditioning module 30 may include circuitry to regulate the voltage from the battery 28 and output the regulated voltage on a power bus 44 that provides electric power to the other components. The power conditioning module 30 may also receive electric charge from the photovoltaic element array 32 which is utilized to charge the battery 28.

The display module 34, as shown in FIG. 1, generally displays data and images to the user according to a mode of operation. For example, in one mode, the display module 34 may display a watch face or the time of day. In another mode, the display module 34 may display a calendar. In still another mode, the display module 34 may display performance data from activities of the user, and so forth. The display module 34 is positioned within the internal cavity of the housing 12 and is surrounded, at least in part, by the side wall 38 and retained by the bezel 40.

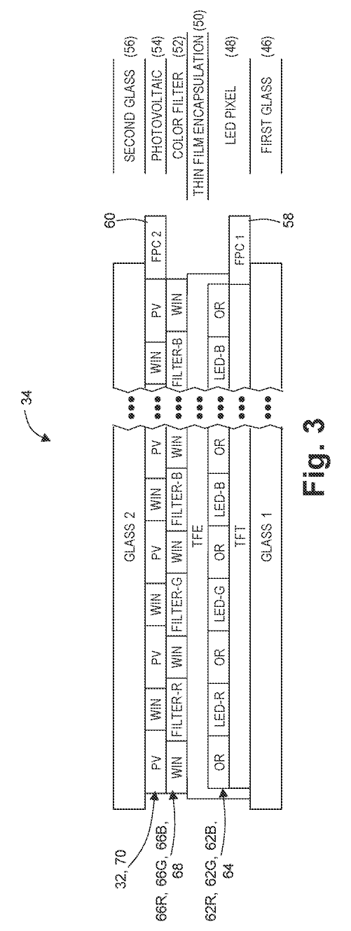

Referring to FIGS. 3-6, the display module 34 may be formed from a plurality of layers of components positioned one on top of another to create a stack. Starting with the lowest layer to the highest layer, the display module 34 stack includes a first glass layer 46, a light-emitting diode (LED) pixel layer 48, a thin film encapsulation layer 50, a color filter layer 52, a photovoltaic layer 54, and a second glass layer 56. Each of the layers may have a general disc shape (following the shape of the internal cavity of the housing 12). The display module 34 further includes, or is in communication with, a first flexible printed circuit 58 and a second flexible printed circuit 60.

The first glass layer 46 is formed from silicon-based materials, sapphire-based materials, or combinations thereof. The first glass layer 46 may provide a structural foundation for the stack of components as well as providing electrical insulation or isolation from other components of the electronic device 10.

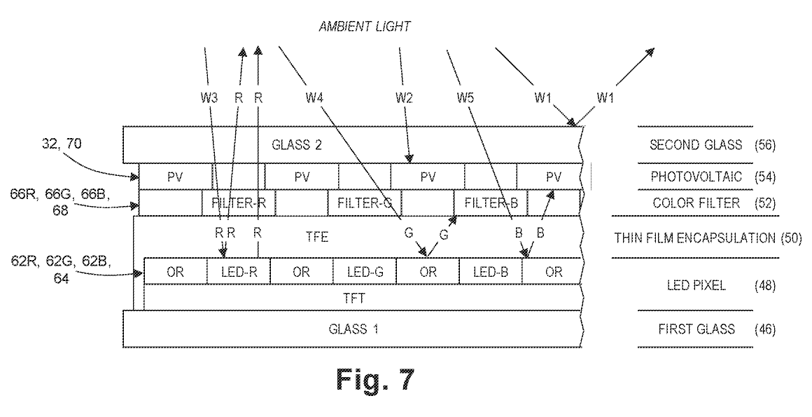

The LED pixel layer 48 generates the data and images displayed by the display module 34 and includes a plurality of pixels 62 and a plurality of optical reflectors 64. Each pixel 62 generates a single point of light and is formed from a plurality of individual subpixels, each subpixel generating a particular color, wavelength of electromagnetic radiation, or range of wavelengths. In exemplary embodiments, the subpixels include a red subpixel 62R, a green subpixel 62G, and a blue subpixel 62B, as is known as “RGB”. Other subpixel colors or color combinations are possible. Each subpixel 62R, 62G, 62Bis formed from, or includes, an LED structure which may include organic material forming an organic LED (OLED), and which may also include one of a plurality of active transistors, i.e., a thin-film transistor (“TFT” in FIGS. 3 and 7), forming an active matrix (AMOLED).

In various embodiments, each of the subpixels 62R, 62G, 62B may be formed using different types of LED structures, including but not limited to organic light-emitting diodes (OLEDs), micro light-emitting diodes (microLEDs), and inorganic LEDs. MicroLED structures may include arrays of microscopic inorganic LEDs directly bonded or transferred onto the substrate of the LED pixel layer 48, offering benefits such as high brightness, long lifespan, and low power consumption. In other embodiments, the subpixels may be formed using hybrid configurations wherein microLEDs are combined with quantum dot enhancement layers to improve color purity and efficiency. Additionally, each subpixel may incorporate a thin-film transistor (TFT) for active matrix addressing, forming an active matrix organic light-emitting diode (AMOLED) or active matrix microLED (AMµLED) display, depending on the LED structure used.

Each red subpixel 62R (“LED-R” in FIGS. 3 and 7) emits light having one or more wavelengths in a first range of wavelengths in a red color portion of the visible spectrum of electromagnetic radiation, wherein the first range may include wavelengths from approximately 620 nanometers (nm) to approximately 750 nm. Each green subpixel 62G (“LED-G” in FIGS. 3 and 7) emits light having one or more wavelengths in a second range of wavelengths in a green color portion of the visible spectrum, wherein the second range may include wavelengths from approximately 495 nm to approximately 570 nm. Each blue subpixel 62B (“LED-B” in FIGS. 3 and 7) emits light having one or more wavelengths in a third range of wavelengths in a blue color portion of the visible spectrum, wherein the third range may include wavelengths from approximately 380 nm to approximately 500 nm.

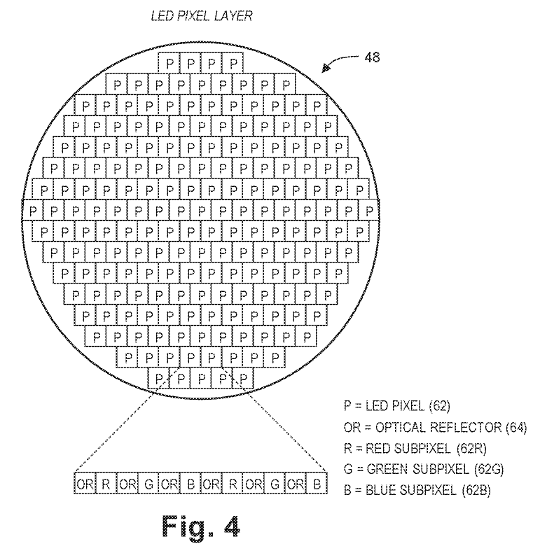

Referring to FIGS. 3 and 4, the subpixels 62R, 62G, 62B are laterally spaced apart from one another and distributed in a first array pattern. In exemplary embodiments, the pattern may be triangular or hexagonal. In other embodiments, the pattern may be an orthogonal grid or the like.

The optical reflectors 64 are each formed from metal, metal alloys, or other materials which reflect a substantial portion of the light (photons) that strike an upper surface thereof. Each optical reflector 64 is positioned in a respective one of the spaces between adjacent subpixels 62R, 62G, 62B.

The thin film encapsulation (TFE) layer 50 is formed from alternating layers of organic and inorganic materials which are deposited to cover the LED pixel layer 48. The materials used to form the TFE layer 50 are generally transparent to light in the visible spectrum. The TFE layer 50 protects the LED pixel layer 48 from oxygen and moisture.

The color filter layer 52 generally filters light at a plurality of different wavelengths or colors and includes a plurality of color filters 66 and a plurality of filter windows 68. Each color filter 66 includes a red subfilter 66R, a green subfilter 66G, and a blue subfilter 66B. The red subfilter 66R (“FILTER-R” in FIGS. 3 and 7) passes light having a wavelength in the first range of wavelengths in the red color portion of the visible spectrum and filters light having a wavelength outside of the first range. The green subfilter 66G (“FILTER-G” in FIGS. 3 and 7) passes light having a wavelength in the second range of wavelengths in the green color portion of the visible spectrum and filters light having a wavelength outside of the second range. The blue subfilter 66B (“FILTER-B” in FIGS. 3 and 7) passes light having a wavelength in the third range of wavelengths in the blue color portion of the visible spectrum and filters light having a wavelength outside of the third range.

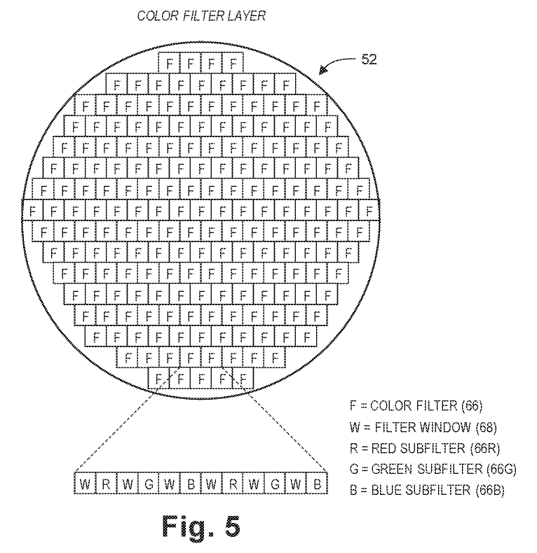

Referring to FIGS. 3 and 5, the subfilters 66R, 66G, 66B are laterally spaced apart from one another and distributed in a second array pattern. In exemplary embodiments, the pattern may be triangular or hexagonal. In other embodiments, the pattern may be an orthogonal grid or the like. A respective one of the filter windows 68 is positioned between adjacent subfilters 66R, 66G, 66B. Each filter window 68 may be formed from glass having transparency to light in the visible spectrum or may be an empty space formed by etching or otherwise removing material from the subfilters 66R, 66G, 66B.

The second array pattern of the color filter layer 52 is positioned relative to the first array pattern of the LED pixel layer 48 so that each filter window 68 is vertically aligned with a respective one of the optical reflectors 64. In addition, each color subfilter 66R, 66G, 66B is vertically aligned with the corresponding color subpixel 62R, 62G, 62B. That is, each red subfilter 66R is vertically aligned with a respective one of the red subpixels 62R. Each green subfilter 66Gis vertically aligned with a respective one of the green subpixels 62G. And, each blue subfilter 66B is vertically aligned with a respective one of the blue subpixels 62B.

The photovoltaic layer 54 generally converts optical energy to electrical energy and includes a plurality of photovoltaic elements 32 and a plurality of photovoltaic windows 70. Each photovoltaic element 32 is formed from one or more layers of doped amorphous silicon which has the advantages of low cost as well as low toxicity compared to some other photovoltaic materials, but it is understood that other photovoltaic materials may be employed without departing from the present teachings such as silicon, micro-crystalline silicon, perovskite, or combinations thereof, e.g., stacked in layers.

Depending on desired performance characteristics and fabrication constraints, the photovoltaic elements 32 of the photovoltaic layer 54 may be formed from a variety of semiconductor materials and multilayer architectures. In addition to doped amorphous silicon (a-Si:H), suitable materials may include microcrystalline silicon (μc-Si), polycrystalline silicon, or monocrystalline silicon, each offering different trade-offs between efficiency, flexibility, and deposition cost. In further embodiments, the photovoltaic elements 32 may incorporate thin-film perovskite materials, such as methylammonium lead halide (e.g., CH₃NH₃PbI₃), known for their high light absorption coefficients and tunable bandgaps. Alternative chemistries may include copper indium gallium selenide (CIGS), cadmium telluride (CdTe), or organic photovoltaic (OPV) compounds utilizing conjugated polymers and small molecules. These materials may be utilized individually or in tandem stacks to broaden the absorption spectrum and enhance conversion efficiency. Additionally, transparent conductive layers such as indium tin oxide (ITO), silver nanowires, or graphene may be used as electrodes to collect charge carriers without obstructing light transmission through the photovoltaic windows 70.

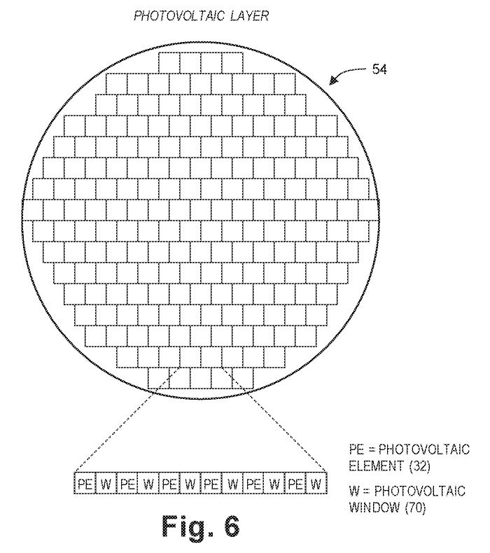

Referring to FIGS. 3 and 6, the photovoltaic elements 32 are laterally spaced apart from one another and distributed in a third array pattern. In exemplary embodiments, the pattern may be triangular or hexagonal. In other embodiments, the pattern may be an orthogonal grid or the like. A respective one of the photovoltaic windows 70 is positioned between adjacent photovoltaic elements 32. Each photovoltaic window 70 may be formed from glass having transparency to light in the visible spectrum or may be an empty space formed by etching or otherwise removing material from the photovoltaic elements 32.

The third array pattern of the photovoltaic layer 54 is positioned relative to the second array pattern of the color filter layer 52 so that each photovoltaic window 70 is vertically aligned with a respective one of the subfilters 66R, 66G, 66B, and each photovoltaic element 32 is vertically aligned with a respective one of the filter windows 68. In addition, the third array pattern of the photovoltaic layer 54 is positioned relative to the first array pattern of the LED pixel layer 48 so that each photovoltaic window 70 is vertically aligned with a respective one of the subpixels 62R, 62G, 62B, and each photovoltaic element 32 is vertically aligned with a respective one of the optical reflectors 64.

In some embodiments, the photovoltaic layer 54 may be configured as a standalone module that is laminated to adjacent layers of the display stack using an optically clear adhesive (OCA) or other transparent bonding materials that maintain optical alignment and transmission characteristics across the stack. The lamination process may be carried out under controlled temperature and pressure conditions to ensure minimal air entrapment and optimal mechanical stability. The photovoltaic layer 54 may be configured as a discrete solar cell by electrically connecting the plurality of photovoltaic elements 32 in series, in parallel, or in a combination thereof, to optimize voltage and current output characteristics based on the available surface area and illumination conditions. In such configurations, the photovoltaic layer 54 may include patterned conductive traces or transparent electrodes to collect and route the generated electrical energy to the power conditioning module 30 via the second flexible printed circuit 60. In various configurations, the optically clear adhesive (OCA) may be omitted or positioned elsewhere in the display stack.

In some embodiments, the photovoltaic layer 54 and the color filter layer 52 may be co-fabricated with the touch-sensitive input component (e.g., touch panel 72) on a common substrate to form a unified optical and functional layer. This integrated PV-CF-TP assembly may then be laminated as a single structure onto the upper surface of the thin film encapsulation (TFE) layer 50 of the LED pixel layer 48. Such a configuration enables the simultaneous alignment of photovoltaic windows 70, color subfilters 66R, 66G, 66B, and touch-sensitive electrodes, while reducing the total number of assembly steps. The integration of photovoltaic and optical filtering functionality with the touch interface can also improve manufacturing yield by simplifying the stack-up and reducing the number of discrete alignment operations. The touch panel 72 may be positioned on either the upper surface, the lower surface, or both surfaces of the second glass layer 56, depending on design considerations and desired input sensitivity. The photovoltaic layer 54 and the color filter layer 52 may be positioned on one surface of the second glass layer 56, while the touch panel 72 is positioned on the opposite surface.

The color filter layer 52 may be positioned in various locations within the display stack depending on process integration, optical performance requirements, and manufacturing strategy. In one embodiment, the color filter layer 52 may be formed on the same substrate as the photovoltaic layer 54, enabling simultaneous patterning and alignment of the color subfilters 66R, 66G, 66B and the photovoltaic windows 70. This configuration facilitates high-precision registration between the filtering and energy-harvesting functions and simplifies the lamination process by allowing both layers to be applied together as a composite structure. In alternative embodiments, the color filter layer 52 may be deposited directly onto the thin film encapsulation (TFE) layer 50 of the LED pixel layer 48.

In alternate embodiments, the photovoltaic layer 54, configured as a standalone module, may be deposited directly onto the upper surface of the thin film encapsulation (TFE) layer 50, eliminating the need for separate lamination. In this configuration, the photovoltaic elements 32 and photovoltaic windows 70 can be patterned using deposition techniques such as physical vapor deposition (PVD), chemical vapor deposition (CVD), photo-lithography, laser, or inkjet printing, depending on the materials employed. This approach allows the photovoltaic layer 54 to conform closely to the underlying TFE layer 50 and the LED pixel layer 48, maintaining precise alignment of the photovoltaic windows 70 with the color subfilters 66R, 66G, 66B and subpixels 62R, 62G, 62B.

In additional embodiments, the photovoltaic layer 54, the display module 34, and a touch-sensitive input component (e.g., touch panel formed position within or on top of the display stack) may be fabricated as discrete, standalone elements that are subsequently joined together during final assembly of the electronic device 10. This modular configuration enables each component to be manufactured, tested, and optimized independently, thereby reducing manufacturing complexity, improving yield, and lowering overall production costs compared to monolithic stack designs where all layers are fabricated in a single integrated process. The discrete elements may be aligned and laminated together using optically clear adhesives or bonding films that preserve optical integrity and mechanical robustness. Electrical interconnections between the photovoltaic layer 54 and the second flexible printed circuit 60, and between the display module 34 and the first flexible printed circuit 58, can be established using anisotropic conductive films (ACFs), flex-on-glass (FoG) processes, or fine-pitch connectors. The touch panel, which may include capacitive or resistive sensing elements, can be positioned above the second glass layer 56 and interfaced with the processor 18 to provide user input functionality without interfering with the energy collection or image display functions of the underlying layers.

In yet another embodiment, the photovoltaic layer 54—particularly when formed from amorphous silicon (a-Si:H) or Perovskite —and the color filter layer 52 may be jointly fabricated on an independent substrate as a standalone module and subsequently laminated onto the upper surface of the TFE layer 50 of the LED pixel layer 48. This approach allows precise processing and alignment of both photovoltaic and color filtering components in a controlled, parallel manufacturing stream prior to integration with the core display module 34. Such a method offers flexibility in material selection and processing temperatures while preserving the integrity of the underlying OLED structures. Additionally or alternatively, embodiments of the present invention can provide for direct deposition of photovoltaic elements—such as a-Si or other solar materials—onto the TFE layer 50 or even within the OLED stack itself, positioned above the pixel-driving layer. This configuration would represent an optimal integration strategy by maximizing the surface area available for solar energy harvesting while minimizing obstruction of emitted light and reducing impact on viewing angle. Integrating solar functionality closer to the emission plane may also reduce optical losses caused by intermediate layers and interfaces, further enhancing the efficiency and compactness of the display module 34.

The second glass layer 56 is formed from silicon-based materials, sapphire-based materials, or combinations thereof that are generally transparent to light in the visible spectrum. The second glass layer 56 may also provide protection for the display module 34.

The first flexible printed circuit 58 (FPC1) is formed from one or more electrically conductive layers and two or more electrically insulating or dielectric layers, wherein each electrically conductive layer is positioned between two electrically insulating or dielectric layers. The electrically conductive layer(s) include a plurality of conductive traces for conducting electronic signals, one or more conductive planes for providing supply voltages or electrical ground, or combinations thereof. The electrically insulating or dielectric layers may be formed from polymers, polyimides, or other similar flexible non-electrically conductive materials. The first flexible printed circuit 58 is electrically connected to the LED pixel layer 48 to conduct electronic data and control signals as well as supply voltages and electrical ground to the LED pixel layer 48.

The second flexible printed circuit 60 (FPC2) may have a similar structure to the first flexible printed circuit 58, including one or more electrically conductive layers and two or more electrically insulating or dielectric layers. The second flexible printed circuit 60 is electrically connected to the photovoltaic layer 54 to conduct the voltage and/or current, i.e., electrical energy, generated by the photovoltaic layer 54.

Referring to FIG. 7, the display module 34 may operate or function as follows. Colored light that is emitted or generated by the color subpixels 62R, 62G, 62B passes through the TFE layer 50 (which is generally transparent to light in the visible spectrum passing through in either direction) and passes through the aligned corresponding color subfilters 66R, 66G, 66B, while light emitted from other color subpixels 62R, 62G, 62B is filtered out. For example, red light R emitted from one of the red subpixels 62R, shown in FIG. 7, passes through the TFE layer 50 and through the aligned red subfilter 66R, while colored light from other colored subpixels 62R, 62G, 62B is filtered out. The red light R then passes through the aligned photovoltaic window 70 and through the second glass layer 56. Colored light emitted by the other color subpixels 62R, 62G, 62B follows a similar path in exiting the display module 34 – that is, passing through the TFE layer 50, the aligned corresponding color subfilter 66R, 66G, 66B, the aligned photovoltaic window 70, and the second glass layer 56.

Ambient light, in the form of rays or beams of white light (W1, W2, W3, W4, W5), shines on the display module 34 from a variety of angles and is filtered, absorbed, reflected, or combinations thereof. For example, a first ray W1 may strike an upper surface of the second glass layer 56 at a shallow angle and be reflected. Light rays that shine on the display module 34 at a steeper angle may pass through the second glass layer 56. A second ray W2 passes through the second glass layer 56 and impacts the photovoltaic elements 32. The ray W2 is absorbed as photonic energy and converted to electrical energy or electric charge, which is output as voltage and/or current through the second flexible printed circuit 60.

A third ray W3 passes through the second glass layer 56, passes through one of the photovoltaic windows 70, and encounters one of the red subfilters 66R, as an example. Red wavelengths pass through the red subfilter 66R, while other wavelengths are filtered out. The ray W3 is now red light R which passes through the TFE layer 50 and strikes an upper surface of one of the red subpixels 62R. The red light R may get absorbed or it may reflect and pass back through the TFE layer 50, the red subfilter 66R, the photovoltaic window 70, and the second glass layer 56.

A fourth ray W4 passes through the second glass layer 56, passes through one of the photovoltaic windows 70, and encounters one of the green subfilters 66G, as an example. Green wavelengths pass through the green subfilter 66G, while other wavelengths are filtered out. The ray W4 is now green light G which passes through the TFE layer 50 and strikes an upper surface of one of the optical reflectors 64. The green light G reflects from the optical reflector 64 and, given its angle of reflection, impacts one of the blue subfilters 66B and is absorbed.

A fifth ray W5 passes through the second glass layer 56, passes through one of the photovoltaic windows 70, and encounters one of the blue subfilters 66B, as an example. Blue wavelengths pass through the blue subfilter 66B, while other wavelengths are filtered out. The ray W5 is now blue light B which passes through the TFE layer 50 and strikes an upper surface of one of the optical reflectors 64. The blue light B reflects from the optical reflector 64 and, given its angle of reflection, passes through one of the photovoltaic windows 70 and impacts one of the photovoltaic elements 32, which absorbs it.

Throughout this specification, references to “one embodiment”, “an embodiment”, or “embodiments” mean that the feature or features being referred to are included in at least one embodiment of the technology. Separate references to “one embodiment”, “an embodiment”, or “embodiments” in this description do not necessarily refer to the same embodiment and are also not mutually exclusive unless so stated and/or except as will be readily apparent to those skilled in the art from the description. For example, a feature, structure, act, etc. described in one embodiment may also be included in other embodiments, but is not necessarily included. Thus, the present technology can include a variety of combinations and/or integrations of the embodiments described herein.

Although the present application sets forth a detailed description of numerous different embodiments, it should be understood that the legal scope of the description is defined by the words of the claims set forth at the end of this patent and equivalents. The detailed description is to be construed as exemplary only and does not describe every possible embodiment since describing every possible embodiment would be impractical. Numerous alternative embodiments may be implemented, using either current technology or technology developed after the filing date of this patent, which would still fall within the scope of the claims.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

The patent claims at the end of this patent application are not intended to be construed under 35 U.S.C. § 112(f) unless traditional means-plus-function language is expressly recited, such as “means for” or “step for” language being explicitly recited in the claim(s).

Although the technology has been described with reference to the embodiments illustrated in the attached drawing figures, it is noted that equivalents may be employed and substitutions made herein without departing from the scope of the technology as recited in the claims.

Having thus described various embodiments of the technology, what is claimed as new and desired to be protected by Letters Patent includes the following:

What is claimed is:

1. A display module for use with a wrist-worn electronic device, the display module comprising:
a plurality of layers positioned one on top of another to form a stack, the layers from a bottom to a top including:
a first glass layer configured to provide electrical isolation for the display module;
a light-emitting diode (LED) pixel layer including a plurality of pixels distributed in a first array pattern, each pixel including a red subpixel, a green subpixel, and a blue subpixel, with the subpixels laterally spaced apart from one another;
a thin film encapsulation (TFE) layer configured to provide a moisture barrier for the LED pixel layer;
a color filter layer including
a plurality of color filters distributed in a second array pattern, each color filter including a red subfilter, a green subfilter, and a blue subfilter, with the subfilters laterally spaced apart from one another, and the red subfilter of each color filter is vertically aligned with the red subpixel of a respective one of the pixels, the green subfilter of each color filter is vertically aligned with the green subpixel of a respective one of the pixels, and the blue subfilter of each color filter is vertically aligned with the blue subpixel of a respective one of the pixels, and
a plurality of filter windows, each filter window positioned between respective adjacent subfilters and configured to pass light having a wavelength in the visible spectrum;
a photovoltaic layer including
a plurality of photovoltaic elements configured to convert optical energy to electrical energy, the photovoltaic elements laterally spaced apart from one another in a third array pattern, and
a plurality of photovoltaic windows, each photovoltaic window positioned between respective adjacent photovoltaic elements and configured to pass light having a wavelength in the visible spectrum, each photovoltaic window being vertically aligned with a respective one of the subfilters of the color filter layer and a respective one of the subpixels of the LED pixel layer; and
a second glass layer configured to be transparent to wavelengths of light in the visible spectrum.

2. The display module of claim 1, further comprising a first flexible printed circuit including a plurality of electrical conductors electrically connected to the LED pixel layer, the electrical conductors configured to conduct electronic signals to the LED pixel layer.

3. The display module of claim 2, further comprising a second flexible printed circuit including a plurality of electrical conductors electrically connected to the photovoltaic layer, the electrical conductors configured to conduct electrical energy from the photovoltaic layer.

4. The display module of claim 1, wherein
the red subpixel of each pixel is formed from a first LED configured to emit light having a wavelength in a first range of wavelengths in a red color portion of the visible spectrum,
the green subpixel of each pixel is formed from a second LED configured to emit light having a wavelength in a second range of wavelengths in a green color portion of the visible spectrum, and
the blue subpixel of each pixel is formed from a third LED configured to emit light having a wavelength in a third range of wavelengths in a blue color portion of the visible spectrum.

5. The display module of claim 4, wherein
the red subfilter of each color filter passes light having a wavelength in the first range of wavelengths in the red color portion of the visible spectrum and filters light having a wavelength outside of the first range,
the green subfilter of each color filter passes light having a wavelength in the second range of wavelengths in the green color portion of the visible spectrum and filters light having a wavelength outside of the second range, and
the blue subfilter of each color filter passes light having a wavelength in the third range of wavelengths in the blue color portion of the visible spectrum and filters light having a wavelength outside of the third range.

6. The display module of claim 1, wherein each filter window is vertically aligned with a respective one of the photovoltaic elements.

7. The display module of claim 1, wherein the LED pixel layer further includes a plurality of optical reflectors, each optical reflector positioned between respective adjacent subpixels and having an upper surface configured to reflect at least a portion of the light striking thereon.

8. The display module of claim 7, wherein each optical reflector is vertically aligned with a respective one of the filter windows and a respective one of the photovoltaic elements.

9. The display module of claim 1, wherein the second glass layer is configured to receive ambient light.

10. The display module of claim 1, wherein the TFE layer extends beyond a perimeter of the LED pixel layer to cover the LED pixel layer.

11. A display module for use with a wrist-worn electronic device, the display module comprising:
a plurality of layers positioned one on top of another to form a stack, the layers from a bottom to a top including:
a first glass layer configured to provide electrical isolation for the display module;
a light-emitting diode (LED) pixel layer including
a plurality of pixels distributed in a first array pattern, each pixel including a red subpixel, a green subpixel, and a blue subpixel, with the subpixels laterally spaced apart from one another, and
a plurality of optical reflectors, each optical reflector positioned between respective adjacent subpixels and having an upper surface configured to reflect at least a portion of the light striking thereon;
a thin film encapsulation (TFE) layer configured to provide a moisture barrier for the LED pixel layer, the TFE extending beyond a perimeter of the LED pixel layer to cover the LED pixel layer;
a color filter layer including
a plurality of color filters distributed in a second array pattern, each color filter including a red subfilter, a green subfilter, and a blue subfilter, with the subfilters laterally spaced apart from one another, and the red subfilter of each color filter is vertically aligned with the red subpixel of a respective one of the pixels, the green subfilter of each color filter is vertically aligned with the green subpixel of a respective one of the pixels, and the blue subfilter of each color filter is vertically aligned with the blue subpixel of a respective one of the pixels, and
a plurality of filter windows, each filter window positioned between respective adjacent subfilters and configured to pass light having a wavelength in the visible spectrum;
a photovoltaic layer including
a plurality of photovoltaic elements configured to convert optical energy to electrical energy, the photovoltaic elements laterally spaced apart from one another in a third array pattern, each photovoltaic element vertically aligned with a respective one of the filter windows and a respective one of the optical reflectors, and
a plurality of photovoltaic windows, each photovoltaic window positioned between respective adjacent photovoltaic elements and configured to pass light having a wavelength in the visible spectrum, each photovoltaic window being vertically aligned with a respective one of the subfilters of the color filter layer and a respective one of the subpixels of the LED pixel layer; and
a second glass layer configured to be transparent to wavelengths of light in the visible spectrum;
a first flexible printed circuit including a plurality of electrical conductors electrically connected to the LED pixel layer, the electrical conductors configured to conduct electronic signals to the LED pixel layer; and
a second flexible printed circuit including a plurality of electrical conductors electrically connected to the photovoltaic layer, the electrical conductors configured to conduct electrical energy from the photovoltaic layer.

12. The display module of claim 11, wherein
the red subpixel of each pixel is formed from a first LED configured to emit light having a wavelength in a first range of wavelengths in a red color portion of the visible spectrum,
the green subpixel of each pixel is formed from a second LED configured to emit light having a wavelength in a second range of wavelengths in a green color portion of the visible spectrum,
the blue subpixel of each pixel is formed from a third LED configured to emit light having a wavelength in a third range of wavelengths in a blue color portion of the visible spectrum,
the red subfilter of each color filter passes light having a wavelength in the first range of wavelengths in the red color portion of the visible spectrum and filters light having a wavelength outside of the first range,
the green subfilter of each color filter passes light having a wavelength in the second range of wavelengths in the green color portion of the visible spectrum and filters light having a wavelength outside of the second range, and
the blue subfilter of each color filter passes light having a wavelength in the third range of wavelengths in the blue color portion of the visible spectrum and filters light having a wavelength outside of the third range.

13. A wrist-worn electronic device, the electronic device comprising:
a housing including a side wall and a bezel connected to an upper edge of the side wall;
a battery configured to supply electric power to components of the electronic device; and
a display module configured to display data and images, the display module positioned within the housing and retained by the bezel, the display module including:
a plurality of layers positioned one on top of another to form a stack, the layers from a bottom to a top including:
a first glass layer configured to provide electrical isolation for the display module;
a light-emitting diode (LED) pixel layer including a plurality of pixels distributed in a first array pattern, each pixel including a red subpixel, a green subpixel, and a blue subpixel, with the subpixels laterally spaced apart from one another;
a thin film encapsulation (TFE) layer configured to provide a moisture barrier for the LED pixel layer;
a color filter layer including
a plurality of color filters distributed in a second array pattern, each color filter including a red subfilter, a green subfilter, and a blue subfilter, with the subfilters laterally spaced apart from one another, and the red subfilter of each color filter is vertically aligned with the red subpixel of a respective one of the pixels, the green subfilter of each color filter is vertically aligned with the green subpixel of a respective one of the pixels, and the blue subfilter of each color filter is vertically aligned with the blue subpixel of a respective one of the pixels, and
a plurality of filter windows, each filter window positioned between respective adjacent subfilters and configured to pass light having a wavelength in the visible spectrum;
a photovoltaic layer including
a plurality of photovoltaic elements configured to convert optical energy to electrical energy that is provided to the battery, the photovoltaic elements laterally spaced apart from one another in a third array pattern, and
a plurality of photovoltaic windows, each photovoltaic window positioned between respective adjacent photovoltaic elements and configured to pass light having a wavelength in the visible spectrum, each photovoltaic window being vertically aligned with a respective one of the subfilters of the color filter layer and a respective one of the subpixels of the LED pixel layer; and
a second glass layer configured to be transparent to wavelengths of light in the visible spectrum.

14. The electronic device of claim 13, wherein
the red subpixel of each pixel is formed from a first LED configured to emit light having a wavelength in a first range of wavelengths in a red color portion of the visible spectrum,
the green subpixel of each pixel is formed from a second LED configured to emit light having a wavelength in a second range of wavelengths in a green color portion of the visible spectrum,
the blue subpixel of each pixel is formed from a third LED configured to emit light having a wavelength in a third range of wavelengths in a blue color portion of the visible spectrum,
the red subfilter of each color filter passes light having a wavelength in the first range of wavelengths in the red color portion of the visible spectrum and filters light having a wavelength outside of the first range,
the green subfilter of each color filter passes light having a wavelength in the second range of wavelengths in the green color portion of the visible spectrum and filters light having a wavelength outside of the second range, and
the blue subfilter of each color filter passes light having a wavelength in the third range of wavelengths in the blue color portion of the visible spectrum and filters light having a wavelength outside of the third range.

15. The electronic device of claim 13, further comprising a first flexible printed circuit including a plurality of electrical conductors electrically connected to the LED pixel layer, the electrical conductors configured to conduct electronic signals to the LED pixel layer.

16. The electronic device of claim 15, further comprising a second flexible printed circuit including a plurality of electrical conductors electrically connected to the photovoltaic layer, the electrical conductors configured to conduct electrical energy from the photovoltaic layer.

17. The electronic device of claim 13, wherein each filter window is vertically aligned with a respective one of the photovoltaic elements.

18. The electronic device of claim 13, wherein the LED pixel layer further includes a plurality of optical reflectors, each optical reflector positioned between respective adjacent subpixels and having an upper surface configured to reflect at least a portion of the light striking thereon.

19. The electronic device of claim 13, wherein each optical reflector is vertically aligned with a respective one of the filter windows and a respective one of the photovoltaic elements.

20. The electronic device of claim 13, wherein the TFE layer extends beyond a perimeter of the LED pixel layer to cover the LED pixel layer.
